(19) United States
(12) Patent Application Publication
(10) Pub. No.: US 2021/0313301 A1
(43) Pub. Date: Oct. 7, 2021

(54) DISPLAY PANEL AND ELECTRONIC DEVICE

(71) Applicant: Shenzhen Royole Technologies Co., Ltd., Shenzhen (CN)

(72) Inventors: Jiahao Kang, Shenzhen (CN); Ze Yuan, Shenzhen (CN); Jie Ni, Shenzhen (CN)

(21) Appl. No.: 17/218,895

(22) Filed: Mar. 31, 2021

(30) Foreign Application Priority Data
Apr. 1, 2020 (CN) 202010250217.3

(51) Int. Cl. H01L 25/075; H01L 23/538; H01L 33/62

(52) U.S. Cl. CPC H01L 25/0753; H01L 33/62; H01L 23/5387

(57) ABSTRACT

The present disclosure provides a display panel including a plurality of light-emitting elements arranged at intervals, and an elastomer covering the plurality of light-emitting elements. Each light-emitting element is provided with a light-emitting region, and a connecting region arranged around the light-emitting region. The light-emitting element includes a light-emitting island arranged in the light-emitting region, and the light-emitting island at least includes an inorganic light-emitting diode. The light-emitting element further includes an elastic connector arranged in the connecting region, and light-emitting islands in two adjacent light-emitting elements are connected via the elastic connector. The present disclosure further provides an electronic device.

### CROSS-REFERENCE TO RELATED APPLICATIONS

The present application claims priority of Chinese Patent Application No. 202010250217.3, filed on Apr. 1, 2020, in China National Intellectual Property Administration, the contents of which are herein incorporated by reference in its entirety.

### FIELD

The present disclosure relates to a technical field of display, and in particular, relates to a display panel and an electronic device.

### BACKGROUND

At present, there are generally two types of display panels, i.e., display panels that emit light with inorganic light-emitting diodes or organic light-emitting diodes. With the demand for flexible display panels in the market, most of the current flexible display panels are made of organic electroluminescent diodes, while few are made of inorganic light-emitting diodes. The main reason is that, in the existing display screens using small-sized inorganic light-emitting diodes and micro-sized inorganic light-emitting diodes, the inorganic light-emitting diode chips are mostly integrated on a rigid substrate, and all these display screens are not flexible.

### SUMMARY

An embodiment of the present disclosure provides a display panel including a plurality of light-emitting elements arranged at intervals, and an elastomer covering the plurality of light-emitting elements. Each light-emitting element is provided with a light-emitting region, and a connecting region arranged around the light-emitting region. The light-emitting element includes a light-emitting island arranged in the light-emitting region, and the light-emitting island at least includes an inorganic light-emitting diode. The light-emitting element further includes an elastic connector arranged in the connecting region, and light-emitting islands in two adjacent light-emitting elements are connected via the elastic connector.

In a further embodiment, the connecting region includes a first connecting region and a second connecting region. The first connecting region includes two parts located on two sides of the light-emitting region along a first direction, and the second connecting region includes two parts located on two sides of the light-emitting region along a second direction. The elastic connector includes a first elastic sub-connector and a second elastic sub-connector. The first elastic sub-connector is arranged in the first connecting region, and the second elastic sub-connector is arranged in the second connecting region. The first elastic sub-connector is configured for receiving a scanning signal, the second elastic sub-connector is configured for receiving a data signal, and the light-emitting island is configured for emitting light under combined effects of the scanning signal and the data signal.

In a further embodiment, the light-emitting island includes an inorganic light-emitting diode. The inorganic light-emitting diode includes a first electrode and a second electrode, the first elastic sub-connector is connected to the first electrode, and the second elastic sub-connector is connected to the second electrode.

In a further embodiment, the first direction extends along a narrow side of the inorganic light-emitting diode, and the second direction extends along a long side of the inorganic light-emitting diode.

In a further embodiment, the light-emitting island includes a pixel. The pixel includes a first inorganic light-emitting diode, a second inorganic light-emitting diode, and a third inorganic light-emitting diode of different colors. The first inorganic light-emitting diode, the second inorganic light-emitting diode, and the third inorganic light-emitting diode are respectively connected to a corresponding second elastic sub-connector, and are commonly connected to a first elastic sub-connector, wherein three second elastic sub-connectors of the pixel are arranged side by side in the second connecting region.

In a further embodiment, the three second elastic sub-connectors of the pixel are led out from the first inorganic light-emitting diode, the second inorganic light-emitting diode, and the third inorganic light-emitting diode on the same side, and extend to the second connecting region. Each of the first inorganic light-emitting diode, the second inorganic light-emitting diode, and the third inorganic light-emitting diode includes a first electrode and a second electrode, and the first elastic sub-connector is led out between the first electrodes and the second electrodes of the first inorganic light-emitting diode, the second inorganic light-emitting diode, and the third inorganic light-emitting diode.

In a further embodiment, the first inorganic light-emitting diode and the second inorganic light-emitting diode are arranged side by side along the narrow side of the first inorganic light-emitting diode, and the third inorganic light-emitting diode is arranged along the long side of the first inorganic light-emitting diode. A central axis of the third inorganic light-emitting diode coincides with a symmetry axis of the first inorganic light-emitting diode and the second inorganic light-emitting diode, and the narrow side of the third inorganic light-emitting diode is perpendicular to the long side of the first inorganic light-emitting diode.

In a further embodiment, the light-emitting island includes a first connector converging point and a second connector converging point located on two sides of the pixel, and first ends of the second elastic sub-connectors which are correspondingly connected to the first inorganic light-emitting diode and the second inorganic light-emitting diode are led out through a gap between the first inorganic light-emitting diode and the second inorganic light-emitting diode and converge at the first connector converging point. A first end of the second elastic sub-connector which is correspondingly connected to the third inorganic light-emitting diode is led out between the first electrode and the second electrode of the third inorganic light-emitting diode, and extends to the first connector converging point via the gap between the first inorganic light-emitting diode and the second inorganic light-emitting diode. Second ends of the second elastic sub-connectors which are correspondingly connected to the first inorganic light-emitting diode and the second inorganic light-emitting diode extend to the second connector converging point around the both sides, respectively, of the third inorganic light-emitting diode, and a second end of the second elastic sub-connector which is correspondingly connected to the third inorganic light-emitting diode is led out between the first electrode and the second electrode of the third inorganic light-emitting diode and extends to the second connector converging point.

In a further embodiment, the first elastic sub-connectors correspondingly connected to the first inorganic light-emitting diode and the second inorganic light-emitting diode are led out between the first electrode and the second electrode of the first inorganic light-emitting diode and the first electrode and the second electrode of the second inorganic light-emitting diode, respectively, and extend to the first connecting region. The first elastic sub-connector correspondingly connected to the third inorganic light-emitting diode is led out from one side of the third inorganic light-emitting diode and extends to the first connecting region.

In a further embodiment, at least one of the first elastic sub-connector and the second elastic sub-connector is curved in the connecting region, and a routing length of at least one of the first elastic sub-connector and the second elastic sub-connector in the connecting region is larger than or equal to a distance between two adjacent light-emitting islands.

In a further embodiment, each light-emitting element includes: a substrate covering the light-emitting region and the connecting region; a first metal layer arranged on one side of the substrate, wherein the first metal layer is arranged in the first connecting region and the light-emitting region, and a part, located in the first connecting region, of the first metal layer is the first elastic sub-connector; a first dielectric layer arranged on one side, away from the substrate, of the first metal layer, wherein the first dielectric layer is at least arranged in the light-emitting region; a second metal layer arranged on one side, away from the first metal layer, of the first dielectric layer, wherein the second metal layer is arranged in the second connecting region and the light-emitting region, and a part, located in the second connecting region, of the second metal layer is the second elastic sub-connector, and the second metal layer is electrically connected to the first metal layer in the light-emitting region; and a second dielectric layer arranged on one side, away from the substrate, of the second metal layer and at least covering the light-emitting region; the inorganic light-emitting diode being arranged on one side, away from the substrate, of the second dielectric layer and electrically connected to the second metal layer.

In a further embodiment, the second metal layer includes a second metal sub-layer and a third metal sub-layer. The inorganic light-emitting diode includes a first electrode and a second electrode. The second metal sub-layer is connected to the first electrode, the third metal sub-layer is connected to the second electrode, and the second metal sub-layer is isolated from the third metal sub-layer in the light-emitting region. The first metal layer is electrically connected to the second electrode via the third metal sub-layer.

In a further embodiment, a through hole is formed in the first dielectric layer. A surface, facing the second metal layer, of the first metal layer and a surface, facing the second metal layer, of the first dielectric layer are connected via the through hole, a connecting pole is arranged in the through hole, and the second metal layer is connected to the first metal layer through the connecting pole.

The present disclosure further provides an electronic device including any one of the display panels described above.

### BRIEF DESCRIPTION OF THE DRAWINGS

In order to more clearly illustrate the technical schemes in embodiments of the present disclosure, the drawings to be used in the embodiments are briefly described below. It is obvious that the drawings in the following description are only some embodiments of the disclosure, and that those skilled in the art can obtain other drawings from these drawings without involving any inventive effort.

FIG. 1 shows a schematic view of a display panel according to a first embodiment of the present disclosure.

FIG. 2 shows a schematic view of a light-emitting element of the display panel according to the first embodiment of the present disclosure.

FIG. 3 shows a sectional view of a light-emitting island of the display panel according to the first embodiment of the present disclosure.

FIG. 4 shows a schematic view of a light-emitting element of a display panel according to a second embodiment of the present disclosure.

FIG. 5 shows a schematic view of a light-emitting island of a display panel according to an embodiment of the present disclosure.

FIG. 6 shows a schematic view of a light-emitting island of a display panel according to a third embodiment of the present disclosure.

FIG. 7 shows a schematic view of an electronic device provided by the present disclosure.

### DETAILED DESCRIPTION

The following description is of the preferred embodiments of the present disclosure, and it is to be understood that numerous modifications and adaptations may be devised by those skilled in the art without departing from the principles of the present disclosure, and such modifications and adaptations are to be considered within the scope of the disclosure.

The terms “first”, “second”, and the like in the description and claims of the disclosure and in the drawings are used for distinguishing between different objects and not for describing a particular order. Furthermore, the terms “include” and “has”, as well as any variations thereof, are intended to cover a non-exclusive inclusion. For example, a process, method, system, article, or apparatus that includes a list of steps or elements is not limited to the listed steps or elements, but optionally further includes steps or elements not listed, or optionally further includes other steps or elements inherent to such process, method, article, or apparatus.

Reference herein to “an embodiment ” means that a particular feature, structure, or characteristic described in connection with the embodiment may be included in at least one embodiment of the disclosure. The appearances of the phrase in various places in the description are not necessarily all referring to the same embodiment, nor are separate or alternative embodiments mutually exclusive of other embodiments. Those skilled in the art will appreciate explicitly and implicitly that the embodiments described herein may be combined with other embodiments.

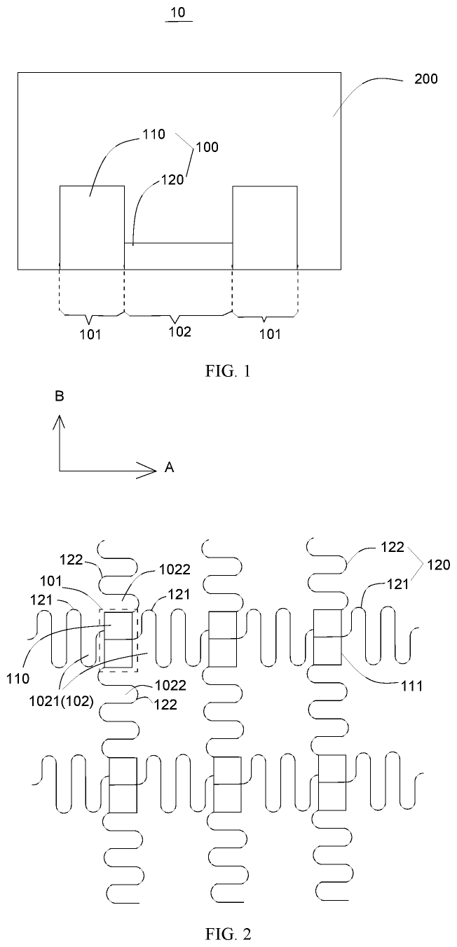

Referring to FIGS. 1 and 2, a first embodiment of the present disclosure provides a display panel 10, and the display panel 10 includes a plurality of light-emitting elements 100 arranged at intervals, and an elastomer 200 covering the plurality of light-emitting elements 100.

Each light-emitting element 100 is provided with a light-emitting region 101, and a connecting region 102 arranged around the light-emitting region 101. The light-emitting element 100 includes a light-emitting island 110 arranged in the light-emitting region 101, and the light-emitting island 110 at least includes an inorganic light-emitting diode 111. An inorganic light-emitting element includes a small-sized or micro-sized inorganic light-emitting element. The light-emitting element 100 further includes an elastic connector 120 arranged in the connecting region 102, and the light-emitting islands 110 in two adjacent light-emitting elements 100 are connected via the elastic connector 120.

According to the present disclosure, the inorganic light-emitting diodes 111 are arranged in the elastomer 200, and the light-emitting islands 110 are connected via the elastic connectors 120, so that the light-emitting elements are formed as islands, thereby allowing the display panel 10 with inorganic light-emitting diodes 111 to be flexible.

Referring to FIG. 2, in a further embodiment, the connecting region 102 includes a first connecting region 1021 and a second connecting region 1022. The first connecting region 1021 includes two parts located on two sides of the light-emitting region 101 along a first direction A, and the second connecting region 1022 includes two parts located on two sides of the light-emitting region 101 along a second direction B. The elastic connector 120 includes a first elastic sub-connector 121 and a second elastic sub-connector 122, the first elastic sub-connector 121 is arranged in the first connecting region 1021, and the second elastic sub-connector 122 is arranged in the second connecting region 1022. That is, the first elastic sub-connector 121 is located on two sides of the light-emitting island 110 along the first direction A, and the second elastic sub-connector 122 is located on two sides of the light-emitting island 110 in the second direction B.

The first elastic sub-connector 121 is configured for receiving a scanning signal, the second elastic sub-connector 122 is configured for receiving a data signal, and the light-emitting island 110 emits light or does not emit light under combined effects of the scanning signal and the data signal.

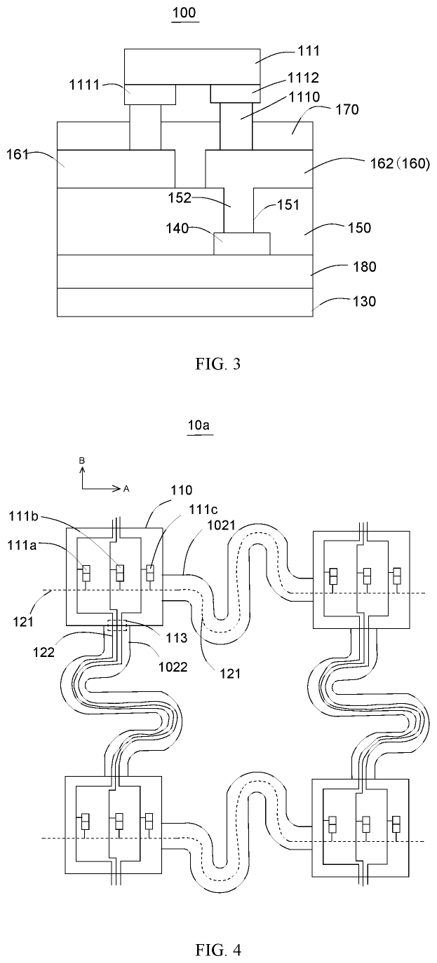

In a further embodiment, the light-emitting island 110 includes an inorganic light-emitting diode 111. The inorganic light-emitting diode 111 includes a first electrode 1111 and a second electrode 1112 (see FIG. 3), the first elastic sub-connector 121 is connected to the first electrode 1111, and the second elastic sub-connector 122 is connected to the second electrode 1112. In this embodiment, the first electrode 1111 is a cathode, and the second electrode 1112 is an anode.

The inorganic light-emitting diodes 111 in adjacent light-emitting islands 110 emit light of different colors, and the colors of light that emitted by the inorganic light-emitting diodes 111 in three light-emitting islands 110 arranged side by side may be red, green and blue, respectively. That is, in this embodiment, the light-emitting island 110 is a sub-pixel, while in other embodiments, the light-emitting island 110 may include a plurality of inorganic light-emitting diodes 111.

In a further embodiment, the first direction A extends along a narrow side of the inorganic light-emitting diode 111, and the second direction B extends along a long side of the inorganic light-emitting diode 111. In other embodiments, the narrow side and the long side of the inorganic light-emitting diode 111 may be interchanged, or in other embodiments, all sides of the inorganic light-emitting diode 111 have the same length.

In a further embodiment, at least one of the first elastic sub-connector 121 and the second elastic sub-connector 122 is curved in the connecting region 102, and the routing length of at least one of the first elastic sub-connector 121 and the second elastic sub-connector 122 in the connecting region 102 is larger than or equal to a distance between two adjacent light-emitting islands 110. The curved shape of the first elastic sub-connector 121 or second elastic sub-connector 122 enables it to be elastic, and when the display panel 10 is stretched, the first elastic sub-connector 121 or the second elastic sub-connector 122 is not easily broken.

In an embodiment, the first elastic sub-connector 121 and the second elastic sub-connector 122 are both curved in the connecting region 102, so that when the display panel 10 is stretched in the first direction A or the second direction B, the first elastic sub-connector 121 and the second elastic sub-connector 122 are both elastic and not easily broken.

Referring to FIG. 3, in a further embodiment, the light-emitting device 100 includes a substrate 130, a first metal layer 140, a first dielectric layer 150, a second metal layer 160, and a second dielectric layer 170.

The substrate 130 covers the light-emitting region 101 and the connecting region 102. The first metal layer 140 is on one side of the substrate 130, wherein the first metal layer 140 is arranged in the first connecting region 1021 and the light-emitting region 101, and a part, located in the first connecting region 1021, of the first metal layer 140 is the first elastic sub-connector 121.

The first dielectric layer 150 is on one side, away from the substrate 130, of the first metal layer 140, wherein the first dielectric layer 150 is at least arranged in the light-emitting region 101. In other embodiments, the first dielectric layer 150 may cover the light-emitting region 101 and the connecting region 102.

The second metal layer 160 is on one side, away from the first metal layer 140, of the first dielectric layer 150, wherein the second metal layer 160 is arranged in the second connecting region 1022 and the light-emitting region 101, a part, located in the second connecting region 1022, of the second metal layer 160 is the second elastic sub-connector 122, and the second metal layer 160 is electrically connected to the first metal layer 140 in the light-emitting region 101. In other embodiments, when the first dielectric layer 150 can cover the light-emitting region 101 and the connecting region 102, the part, located in the second connecting region 1022, of the second metal layer 160 is disposed on a surface, away from the substrate 130, of the first dielectric layer 150.

The second dielectric layer 170 is on one side, away from the substrate 130, of the second metal layer 160, and at least covers the light-emitting region 101; and the inorganic light-emitting diode 111 is arranged on one side, away from the substrate 130 of the second dielectric layer 170 and is electrically connected to the second metal layer 160. In this embodiment, a side, facing the second metal layer 160, of the inorganic light-emitting diode 111 is provided with solder paste 1110, and the solder paste 1110 is connected to the second metal layer 160 via a through hole in the second dielectric layer 170.

In a further embodiment, the second metal layer 160 includes a second metal sub-layer 161 and a third metal sub-layer 162, the inorganic light-emitting diode 111 includes a first electrode 1111 and a second electrode 1112, the second metal sub-layer 161 is connected to the first electrode 1111, the third metal sub-layer 162 is connected to the second electrode 112, and the second metal sub-layer 161 is isolated from the third metal sub-layer 162 in the light-emitting region 101; and the first metal layer 140 is electrically connected to the second electrode 1112 via the third metal sub-layer 162. In this embodiment, the first electrode 1111 and the second electrode 1112 are fixed to the second metal layer 160 by welding with the solder paste 1110.

In a further embodiment, a through hole 151 is formed in the first dielectric layer 150, a surface, facing the second metal layer 160, of the first metal layer 140 and a surface, facing the second metal layer 160, of the first dielectric layer 150 are connected via the through hole 151, a connecting pole 152 is arranged in the through hole 151, and the second metal layer 160 is connected to the first metal layer 140 through the connecting pole 152. In this embodiment, the connecting pole 152 and the second metal layer 160 are deposited simultaneously, and may be of same or different materials.

In a further embodiment, the light-emitting element 100 further includes a buffer layer 180, wherein the buffer layer 180 is arranged on one side of the substrate 130 and covers the light-emitting region 101 and the connecting region 102; and the first metal layer 140 is disposed on a surface, away from the substrate 130, of the buffer layer 180.

Referring to FIG. 4, a second embodiment of the present disclosure provides a display panel 10a which differs from the display panel of the first embodiment in that, in the display panel 10a, a light-emitting island 110 include a pixel which includes a first inorganic light-emitting diode 111a, a second inorganic light-emitting diode 111b, and a third inorganic light-emitting diode 111c of different colors. In this embodiment, the first inorganic light-emitting diode 111a is red, the second inorganic light-emitting diode 111b is green, and the third inorganic light-emitting diode 111c is blue.

Each of the first inorganic light-emitting diode 111a, the second inorganic light-emitting diode 111b, and the third inorganic light-emitting diode 111c is connected to a corresponding second elastic sub-connector 122, and all the first inorganic light-emitting diode 111a, the second inorganic light-emitting diode 111b and the third inorganic light-emitting diode 111c are connected to a common first elastic sub-connector 121. The three second elastic sub-connectors 122 of the pixel are arranged side by side in the second connecting region 1022. Specifically, one light-emitting island 110 has two connector converging points 113 on two sides in the second direction B, and the two ends of the three second elastic sub-connectors 122 extend out of the light-emitting island 110 from the connector converging points 113 on two sides, respectively, and then are arranged side by side in the second connecting region 1022. The side-by-side arrangement of the three second elastic sub-connectors 122 can save wiring space, and increase the density of the inorganic light-emitting diodes 111 of the display panel 10a, thereby improving the display effect. On the other hand, the space around the elastic connector 120 is freed up so that the elastomer 200 fills the space around the elastic link 120 to enhance elasticity.

In a further embodiment, the three second elastic sub-connectors 122 of the pixel are led out from the first inorganic light-emitting diode 111a, the second inorganic light-emitting diode 111b, and the third inorganic light-emitting diode 111c on the same side, and extend to the second connecting region 1022. The three second elastic sub-connectors 121 of the pixel are led out from the first inorganic light-emitting diode 111a, the second inorganic light-emitting diode 111b and the third inorganic light-emitting diode 111c on the same side, and extend to the second connecting region 1021.

It should be noted that, in order to distinguish the first elastic sub-connector 121 from the second elastic sub-connector 122, in FIGS. 4 to 6, the first elastic sub-connector 121 is shown in dotted lines, and the second elastic sub-connector 122 is shown in solid lines for clarity of illustration.

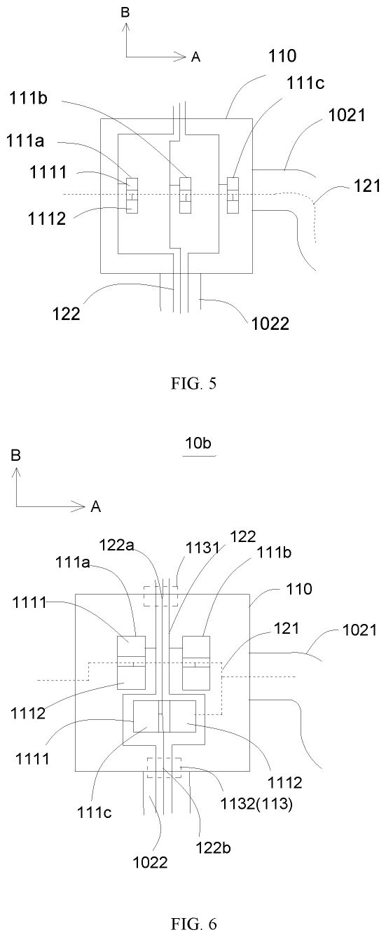

Referring to FIG. 5, in other embodiments, the three second elastic sub-connectors 122 of the pixel are led out from the first inorganic light-emitting diode 111a, the second inorganic light-emitting diode 111b, and the third inorganic light-emitting diode 111c on the same side, and extend to the second connecting region 1022; and each of the first inorganic light-emitting diode 111a, the second inorganic light-emitting diode 111b, and the third inorganic light-emitting diode 111c includes a first electrode 1111 and a second electrode 1112, and the first elastic sub-connector 121 is led out between the first electrode 1111 and the second electrode 1112 of the first inorganic light-emitting diode 111a, the second inorganic light-emitting diode 111b, or the third inorganic light-emitting diode 111c. This arrangement makes the wiring in the display panel 10a neat and regular, saving the wiring space.

Referring to FIG. 6, a third embodiment of the present disclosure provides a display panel 10b,which differs from the display panel of the second embodiment in that, in the display panel 10b, the first inorganic light-emitting diode 111a and the second inorganic light-emitting diode 111b are arranged side by side along the narrow side of the first inorganic light-emitting diode 111a, and the third inorganic light-emitting diode 111c is arranged along the long side of the first inorganic light-emitting diode 111a, and a central axis of the third inorganic light-emitting diode 111c coincides with a symmetry axis of the first inorganic light-emitting diode 111a and the second inorganic light-emitting diode 111b, and the narrow side of the third inorganic light-emitting diode 111c is perpendicular to the long side of the first inorganic light-emitting diode 111a.

In this embodiment, the narrow side of the first inorganic light-emitting diode 111a is the first direction A, and the long side of the first inorganic light-emitting diode 111a is the second direction B. Compared with the arrangement of the three inorganic light-emitting diodes in the second embodiment, the arrangement of the three inorganic light-emitting diodes in this embodiment can reduce the area of the pixel, and the area of the light-emitting island 110 is reduced by about 30%, thereby increasing the pixel density of the display panel 10c; or with the same number of pixels, the wiring space of the elastic connector 120 between the pixels can be increased, thereby enhancing the flexibility of the display panel 10c. In this embodiment, the ratio of the narrow side to the long side may be 1:2.

In a further embodiment, the light-emitting island 110 includes a first connector converging point 1131 and a second connector converging point 1132 located on two sides of the pixel, and in this embodiment, the first connector converging point 1131 and the second connector converging point 1132 are located on two sides of the pixel along the second direction B. first ends 122a of the second elastic sub-connectors 122 which are correspondingly connected to the first inorganic light-emitting diode 111a and the second inorganic light-emitting diode 111b are led out through a gap between the first inorganic light-emitting diode 111a and the second inorganic light-emitting diode 111b and converge at the first connector converging point 1131.

A first end 122a of the second elastic sub-connector 122 which is correspondingly connected to the third inorganic light-emitting diode 111c is led out between the first electrode 1111 and the second electrode 1112 of the third inorganic light-emitting diode 111c, and extends to the first connector converging point 1131 via the gap between the first inorganic light-emitting diode 111a and the second inorganic light-emitting diode 111b; and then the first ends 122a of the three second elastic sub-connectors 122 converge at the first connector converging point 1131 extend side-by-side into the second connecting region 1022. All the first ends 122a of the three elastic sub-connectors 122 of the three inorganic light-emitting diodes are led out through the gap between the first inorganic light-emitting diode 111a and the second inorganic light-emitting diode 111b and extend to the first connector converging point 1131, so that the wiring space can be saved, and the density of the light-emitting islands 110 can be increased.

Second ends 122b of the second elastic sub-connectors 122 which are correspondingly connected to the first inorganic light-emitting diode 111a and the second inorganic light-emitting diode 111b extend to the second connector converging point 1132 around the both sides, respectively, of the third inorganic light-emitting diode 111c, and a second end 122b of the second elastic sub-connector 122 which is correspondingly connected to the third inorganic light-emitting diode 111c is led out between the first electrode 1111 and the second electrode 1112 of the third inorganic light-emitting diode 111c and extends to the second connector converging point 1132. Then the first ends 122b of the three second elastic sub-connectors 122 converge at the second connector converging point 1132 extend side-by-side into the second connecting region 1022.

In this embodiment, the first elastic sub-connectors 121 correspondingly connected to the first inorganic light-emitting diode 111a and the second inorganic light-emitting diode 111b are led out between the first electrode 1111 and the second electrode 1112 of the first inorganic light-emitting diode 111a and the first electrode 1111 and the second electrode 1112 of the second inorganic light-emitting diode 111b, respectively, and extend to the first connecting region 1021, and the first elastic sub-connector 121 correspondingly connected to the third inorganic light-emitting diode 111c is led out from one side of the third inorganic light-emitting diode 111c and extends to the first connecting region 1021. In an embodiment, the one side of the third inorganic light-emitting diode 111c is a narrow side of the third inorganic light-emitting diode 111c.

In this embodiment, with the above wiring arrangement, the wiring space in the light-emitting island 110 can be saved, and the wiring is more orderly.

It should be noted that in other embodiments, the number of inorganic light-emitting diodes in each light-emitting island 110 may also be 2, 4, 5, etc., and may be set according to the composition and size of the display panel.

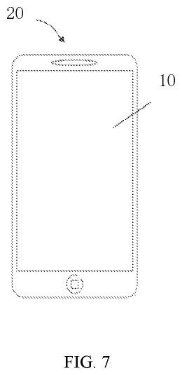

Referring to FIG. 7, the present disclosure further provides an electronic device 20 including the display panel 10 described in any aforementioned embodiment. The electronic device 20 may be, but is not limited to, an electronic book, a smart phone (e.g., Android phone, iOS phone, Windows Phone, etc.), a tablet computer, a flexible palm-top computer, a flexible notebook computer, a mobile Internet device (MID), or a wearable device.

The above-described embodiments illustrate only a few embodiments of the present disclosure, which are described in greater detail, but are not to be construed as limiting the scope of the disclosure. It is to be noted that numerous modifications and adaptations may be devised by those skilled in the art without departing from the principles of the present disclosure, and such modifications and adaptations are to be considered within the scope of the disclosure. Therefore, the scope of protection of the patent for disclosure shall be determined by the appended claims.

What is claimed is:

1. A display panel, comprising:
a plurality of light-emitting elements arranged at intervals, and an elastomer covering the plurality of light-emitting elements;
wherein each light-emitting element is provided with a light-emitting region, and a connecting region arranged around the light-emitting region, wherein the light-emitting element comprises a light-emitting island arranged in the light-emitting region, and the light-emitting island at least comprises an inorganic light-emitting diode, wherein the light-emitting element further comprises an elastic connector arranged in the connecting region, and light-emitting islands in two adjacent light-emitting elements are connected via the elastic connector.

2. The display panel according to claim 1, wherein the connecting region comprises a first connecting region and a second connecting region, the first connecting region comprising two parts located on two sides of the light-emitting region along a first direction, the second connecting region comprising two parts located on two sides of the light-emitting region along a second direction; wherein the elastic connector comprises a first elastic sub-connector and a second elastic sub-connector, the first elastic sub-connector arranged in the first connecting region, the second elastic sub-connector arranged in the second connecting region; and
wherein the first elastic sub-connector is configured for receiving a scanning signal, the second elastic sub-connector is configured for receiving a data signal, and the light-emitting island is configured for emitting light under combined effects of the scanning signal and the data signal.

3. The display panel according to claim 2, wherein the light-emitting island comprises an inorganic light-emitting diode which comprises a first electrode and a second electrode, the first elastic sub-connector connected to the first electrode, and the second elastic sub-connector connected to the second electrode.

4. The display panel according to claim 2, wherein the first direction extends along a narrow side of the inorganic light-emitting diode, and the second direction extends along a long side of the inorganic light-emitting diode.

5. The display panel according to claim 2, wherein the light-emitting island comprises a pixel which comprises a first inorganic light-emitting diode, a second inorganic light-emitting diode, and a third inorganic light-emitting diode of different colors; the first inorganic light-emitting diode, the second inorganic light-emitting diode, and the third inorganic light-emitting diode respectively connected to a corresponding second elastic sub-connector, and commonly connected to first elastic sub-connector, wherein three second elastic sub-connectors of the pixel are arranged side by side in the second connecting region.

6. The display panel according to claim 5, wherein the three second elastic sub-connectors of the pixel are led out from the first inorganic light-emitting diode, the second inorganic light-emitting diode, and the third inorganic light-emitting diode on the same side, and extend to the second connecting region; and
wherein each of the first inorganic light-emitting diode, the second inorganic light-emitting diode, and the third inorganic light-emitting diode comprises a first electrode and a second electrode, and the first elastic sub-connector is led out between the first electrodes and the second electrodes of the first inorganic light-emitting diode, the second inorganic light-emitting diode, and the third inorganic light-emitting diode.

7. The display panel according to claim 5, wherein the first inorganic light-emitting diode and the second inorganic light-emitting diode are arranged side by side along the narrow side of the first inorganic light-emitting diode, and the third inorganic light-emitting diode is arranged along the long side of the first inorganic light-emitting diode, wherein a central axis of the third inorganic light-emitting diode coincides with a symmetry axis of the first inorganic light-emitting diode and the second inorganic light-emitting diode, and the narrow side of the third inorganic light-emitting diode is perpendicular to the long side of the first inorganic light-emitting diode.

8. The display panel according to claim 7, wherein the light-emitting island comprises a first connector converging point and a second connector converging point located on two sides of the pixel, and first ends of the second elastic sub-connectors which are correspondingly connected to the first inorganic light-emitting diode and the second inorganic light-emitting diode are led out through a gap between the first inorganic light-emitting diode and the second inorganic light-emitting diode and converge at the first connector converging point;
wherein a first end of the second elastic sub-connector which is correspondingly connected to the third inorganic light-emitting diode is led out between the first electrode and the second electrode of the third inorganic light-emitting diode, and extends to the first connector converging point via the gap between the first inorganic light-emitting diode and the second inorganic light-emitting diode; and
wherein second ends of the second elastic sub-connectors which are correspondingly connected to the first inorganic light-emitting diode and the second inorganic light-emitting diode extend to the second connector converging point around two sides, respectively, of the third inorganic light-emitting diode, and a second end of the second elastic sub-connector which is correspondingly connected to the third inorganic light-emitting diode is led out between the first electrode and the second electrode of the third inorganic light-emitting diode and extends to the second connector converging point.

9. The display panel according to claim 8, wherein the first elastic sub-connectors correspondingly connected to the first inorganic light-emitting diode and the second inorganic light-emitting diode are led out between the first electrode and the second electrode of the first inorganic light-emitting diode and the first electrode and the second electrode of the second inorganic light-emitting diode respectively, and extend to the first connecting region, and the first elastic sub-connector correspondingly connected to the third inorganic light-emitting diode is led out from one side of the third inorganic light-emitting diode and extends to the first connecting region.

10. The display panel according to claim 2, wherein at least one of the first elastic sub-connector and the second elastic sub-connector is curved in the connecting region, and a routing length of at least one of the first elastic sub-connector and the second elastic sub-connector in the connecting region is larger than or equal to a distance between two adjacent light-emitting islands.

11. The display panel according to claim 2, wherein each light-emitting element comprises:
a substrate covering the light-emitting region and the connecting region;
a first metal layer arranged on one side of the substrate, wherein the first metal layer is arranged in the first connecting region and the light-emitting region, and a part, located in the first connecting region, of the first metal layer is the first elastic sub-connector;
a first dielectric layer arranged on one side, away from the substrate, of the first metal layer, wherein the first dielectric layer is at least arranged in the light-emitting region;
a second metal layer arranged on one side, away from the first metal layer, of the first dielectric layer, wherein the second metal layer is arranged in the second connecting region and the light-emitting region, and a part, located in the second connecting region, of the second metal layer is the second elastic sub-connector, and the second metal layer is electrically connected to the first metal layer in the light-emitting region; and
a second dielectric layer arranged on one side, away from the substrate, of the second metal layer and at least covering the light-emitting region, the inorganic light-emitting diode being arranged on one side, away from the substrate, of the second dielectric layer and electrically connected to the second metal layer.

12. The display panel according to claim 11, wherein the second metal layer comprises a second metal sub-layer and a third metal sub-layer, and the inorganic light-emitting diode comprises a first electrode and a second electrode, the second metal sub-layer connected to the first electrode, the third metal sub-layer connected to the second electrode, and the second metal sub-layer isolated from the third metal sub-layer in the light-emitting region, wherein the first metal layer is electrically connected to the second electrode via the third metal sub-layer.

13. The display panel according to claim 11, wherein a through hole is formed in the first dielectric layer; a surface, facing the second metal layer, of the first metal layer and a surface, facing the second metal layer, of the first dielectric layer are connected via the through hole, a connecting pole arranged in the through hole, and the second metal layer connected to the first metal layer through the connecting pole.

14. An electronic device, comprising a display panel;
wherein the display panel comprises:
a plurality of light-emitting elements arranged at intervals, and an elastomer covering the plurality of light-emitting elements;
wherein each light-emitting element is provided with a light-emitting region, and a connecting region arranged around the light-emitting region, wherein the light-emitting element comprises a light-emitting island arranged in the light-emitting region, and the light-emitting island at least comprises an inorganic light-emitting diode, wherein the light-emitting element further comprises an elastic connector arranged in the connecting region, and light-emitting islands in two adjacent light-emitting elements are connected via the elastic connector.

15. The electronic device according to claim 14, wherein the connecting region comprises a first connecting region and a second connecting region, the first connecting region comprising two parts located on two sides of the light-emitting region along a first direction, the second connecting region comprising two parts located on two sides of the light-emitting region along a second direction; wherein the elastic connector comprises a first elastic sub-connector and a second elastic sub-connector, the first elastic sub-connector arranged in the first connecting region, the second elastic sub-connector arranged in the second connecting region; and
wherein the first elastic sub-connector is configured for receiving a scanning signal, the second elastic sub-connector is configured for receiving a data signal, and the light-emitting island is configured for emitting light under combined effects of the scanning signal and the data signal.

16. The electronic device according to claim 15, wherein the light-emitting island comprises an inorganic light-emitting diode which comprises a first electrode and a second electrode, the first elastic sub-connector connected to the first electrode, and the second elastic sub-connector connected to the second electrode.

17. The electronic device according to claim 15, wherein the light-emitting island comprises a pixel which comprises a first inorganic light-emitting diode, a second inorganic light-emitting diode, and a third inorganic light-emitting diode of different colors; the first inorganic light-emitting diode, the second inorganic light-emitting diode, and the third inorganic light-emitting diode respectively connected to a corresponding second elastic sub-connector, and commonly connected to first elastic sub-connector, wherein three second elastic sub-connectors of the pixel are arranged side by side in the second connecting region.

18. The electronic device according to claim 17, wherein the three second elastic sub-connectors of the pixel are led out from the first inorganic light-emitting diode, the second inorganic light-emitting diode, and the third inorganic light-emitting diode on the same side, and extend to the second connecting region; and
wherein each of the first inorganic light-emitting diode, the second inorganic light-emitting diode, and the third inorganic light-emitting diode comprises a first electrode and a second electrode, and the first elastic sub-connector is led out between the first electrodes and the second electrodes of the first inorganic light-emitting diode, the second inorganic light-emitting diode, and the third inorganic light-emitting diode.

19. The electronic device according to claim 15, wherein at least one of the first elastic sub-connector and the second elastic sub-connector is curved in the connecting region, and a routing length of at least one of the first elastic sub-connector and the second elastic sub-connector in the connecting region is larger than or equal to a distance between two adjacent light-emitting islands.

20. The electronic device according to claim 15, wherein each light-emitting element comprises:
a substrate covering the light-emitting region and the connecting region;
a first metal layer arranged on one side of the substrate, wherein the first metal layer is arranged in the first connecting region and the light-emitting region, and a part, located in the first connecting region, of the first metal layer is the first elastic sub-connector;
a first dielectric layer arranged on one side, away from the substrate, of the first metal layer, wherein the first dielectric layer is at least arranged in the light-emitting region;
a second metal layer arranged on one side, away from the first metal layer, of the first dielectric layer, wherein the second metal layer is arranged in the second connecting region and the light-emitting region, and a part, located in the second connecting region, of the second metal layer is the second elastic sub-connector, and the second metal layer is electrically connected to the first metal layer in the light-emitting region; and
a second dielectric layer arranged on one side, away from the substrate, of the second metal layer and at least covering the light-emitting region, the inorganic light-emitting diode being arranged on one side, away from the substrate, of the second dielectric layer and electrically connected to the second metal layer.
